(19) United States
(12) Patent Application Publication
(10) Pub. No.: US 2026/0114240 A1
(43) Pub. Date: Apr. 23, 2026

(54) SiC Device Fabrication via an Improved Epitaxy and Implant Approach

(71) Applicant: Applied Materials, Inc., Santa Clara, CA (US)

(72) Inventors: Nan Zheng, Malden, MA (US); Supakit Charnvanichborikarn, Gloucester, MA (US); Hans-Joachim Ludwig Gossmann, Summit, NJ (US); William Robert Bogiages, JR., Danvers, MA (US); Wei Zou, Lexington, MA (US)

(21) Appl. No.: 18/923,476

(22) Filed: Oct. 22, 2024

(51) Int. Cl. H01L 21/66; H01L 21/02; H01L 21/04; H01L 29/66

(52) U.S. Cl. CPC H10P 74/203; H10D 12/031; H10D 62/8325; H10D 64/01366; H10P 14/3442; H10P 30/2042; H10P 30/21

(57) ABSTRACT

Methods for fabricating SiC MOSFETs using compensating ion implants are disclosed. An n-type silicon carbide layer is epitaxially grown. After this growth process, a compensating ion implantation process is performed. This ion implantation process is used to compensate for the known dopant non-uniformity in the n-type silicon carbide layer. After the dopant concentration has been compensated, the traditional processes used to fabricate a planar SiC MOSFET may be performed. For super junction MOSFETs, the n-type epitaxial growth and compensating ion implantation processes may be repeated a plurality of times.

### FIELD

This disclosure describes methods for fabricating SiC MOSFET devices, and more particularly, fabricating MOSFETs using implants to compensate for doping non-uniformity of the epitaxial silicon carbide.

### BACKGROUND

Recently, the use of silicon carbide (SiC) has grown. Several different types of Metal-Oxide-Semiconductor Field-Effect Transistors (MOSFETs) may be created using SiC.

A MOSFET may be formed by epitaxial growth of an n-doped silicon carbide layer on a substrate. A p-type implant may then be performed to create the p-type wells. An n-type implant is then performed in the p-type wells to create the source regions. Back End of Line (BEoL) processes are then performed to add the gate and source and drain contacts.

The fabrication of super junction MOSFETs may be more complex than that described above. Specifically, the creation of p-doped columns is achieved through multiple sequential epitaxial growth and p-type ion implantation processes. After columns of the desired height have been formed, the source and drain regions are created as described above. Finally, BEoL processes are used to add the gate and source and drain contacts.

One issue associated with the formation of these MOSFETs is the uniformity of the epitaxially grown n-type silicon carbide. For example, the apparatus used for the epitaxial growth may have a non-uniform doping profile. In some embodiments, the amount of dopant that is added to the silicon carbide is greater near the center of the workpiece and decreases moving radially outward. This non-uniformity may be problematic, and may cause device performance degradation. For example, parameters, such as breakdown voltage and on-resistance, may be degraded because of this non-uniformity.

Therefore, it would be beneficial if there were a method of fabricating these devices that created a more uniformly doped n-type epitaxially grown silicon carbide layer. Further, it would be advantageous if this method was applicable to a variety of different types of devices.

### SUMMARY

Methods for fabricating SiC MOSFETs using compensating ion implants are disclosed. An n-type silicon carbide layer is epitaxially grown. After this growth process, a compensating ion implantation process is performed. This ion implantation process is used to compensate for the known dopant non-uniformity in the n-type silicon carbide layer. After the dopant concentration has been compensated, the traditional processes used to fabricate a planar or trench type SiC MOSFET may be performed. For super junction MOSFETs, the n-type epitaxial growth and compensating ion implantation processes may be repeated a plurality of times.

According to one embodiment, a method of fabricating a planar silicon carbide MOSFET is disclosed. The method comprises growing an epitaxial layer on a substrate using an epitaxy reactor, wherein the epitaxial layer is in-situ doped using a first n-type species; determining a dose profile to compensate for non-uniformity of a dopant concentration of the epitaxial layer; performing a compensating ion implantation using a second n-type species into the epitaxial layer based on the dose profile; implanting a p-type species into portions of the epitaxial layer to form p-wells; implanting a third n-type species into the p-wells to form source regions; forming a gate on a top surface of the epitaxial layer between the p-wells; and adding contacts for the source regions, the gate and a drain region. In some embodiments, the method comprises measuring the dopant concentration of the epitaxial layer as a function of position after the growing, wherein the dopant concentration as a function of position defines the non-uniformity of the dopant concentration. In certain embodiments, the measuring is performed non-destructively. In some embodiments, the non-uniformity of the dopant concentration is determined using a different substrate. In certain embodiments, the method comprises growing a sacrificial epitaxial layer on a sacrificial substrate using the epitaxy reactor, wherein the sacrificial epitaxial layer is in-situ doped using the first n-type species; and measuring the dopant concentration of the sacrificial epitaxial layer as a function of position, wherein the dopant concentration as a function of position is used as the non-uniformity of the dopant concentration of the epitaxial layer. In certain embodiments, the measuring is performed destructively.

According to another embodiment, a method of fabricating a silicon carbide super junction MOSFET is disclosed. The method comprises growing an epitaxial layer on a substrate using an epitaxy reactor, wherein the epitaxial layer is in-situ doped using a first n-type species; determining a dose profile to compensate for non-uniformity of a dopant concentration of the epitaxial layer; performing a compensating ion implantation using a second n-type species into the epitaxial layer based on the dose profile; implanting a first p-type species into portions of the epitaxial layer to form p-doped columns; repeating the growing, performing and implanting a plurality of times to achieve a desired height of the p-doped columns; and after the desired height has been achieved: implanting a second p-type species into portions of the epitaxial layer to form p-wells; implanting a third n-type species into the p-wells to form source regions; forming a gate on a top surface of the additional epitaxial layer between the p-wells; and adding contacts for the source regions, the gate and a drain region. In some embodiments, the method comprises measuring the dopant concentration of the epitaxial layer as a function of position after the growing, wherein the dopant concentration as a function of position defines the non-uniformity of the dopant concentration. In certain embodiments, the measuring is performed non-destructively. In some embodiments, the non-uniformity of the dopant concentration is determined using a different substrate. In certain embodiments, the method comprises growing a sacrificial epitaxial layer on a sacrificial substrate using the epitaxy reactor, wherein the sacrificial epitaxial layer is in-situ doped using the first n-type species; and measuring the dopant concentration of the sacrificial epitaxial layer as a function of position, wherein the dopant concentration as a function of position is used as the non-uniformity of the dopant concentration of the epitaxial layer. In certain embodiments, the measuring is performed destructively. In some embodiments, the method comprises growing an additional epitaxial layer after the desired height is achieved, and forming the p-wells in the additional epitaxial layer. In certain embodiments, the non-uniformity of the dopant concentration of the additional epitaxial layer is assumed to be the same as the epitaxial layer.

According to another embodiment, a method of fabricating a silicon carbide trench MOSFET is disclosed. The method comprises growing an epitaxial layer on a substrate using an epitaxy reactor, wherein the epitaxial layer is in-situ doped using a first n-type species; determining a dose profile to compensate for non-uniformity of a dopant concentration of the epitaxial layer; performing a compensating ion implantation using a second n-type species into the epitaxial layer based on the dose profile; implanting a p-type species into portions of the epitaxial layer to create a p-type region; etching a trench into the p-type region to form p-wells; implanting a third n-type species into the p-wells to form source regions; forming a gate in the trench; and adding contacts for the source regions, the gate and a drain region. In some embodiments, the method comprises measuring the dopant concentration of the epitaxial layer as a function of position after the growing, wherein the dopant concentration as a function of position defines the non-uniformity of the dopant concentration. In certain embodiments, the measuring is performed non-destructively. In some embodiments, the non-uniformity of the dopant concentration is determined using a different substrate. In certain embodiments, the method comprises growing a sacrificial epitaxial layer on a sacrificial substrate using the epitaxy reactor, wherein the sacrificial epitaxial layer is in-situ doped using the first n-type species; and measuring the dopant concentration of the sacrificial epitaxial layer as a function of position, wherein the dopant concentration as a function of position is used as the non-uniformity of the dopant concentration of the epitaxial layer. In certain embodiments, the measuring is performed destructively.

### BRIEF DESCRIPTION OF THE FIGURES

For a better understanding of the present disclosure, reference is made to the accompanying drawings, which are incorporated herein by reference and in which:

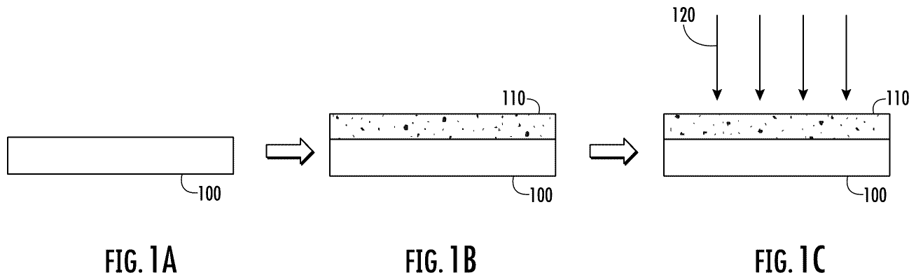

### FIGS. 1A-1C SHOW FABRICATION PROCESSES THAT ARE COMMON FOR

forming a SiC MOSFET;

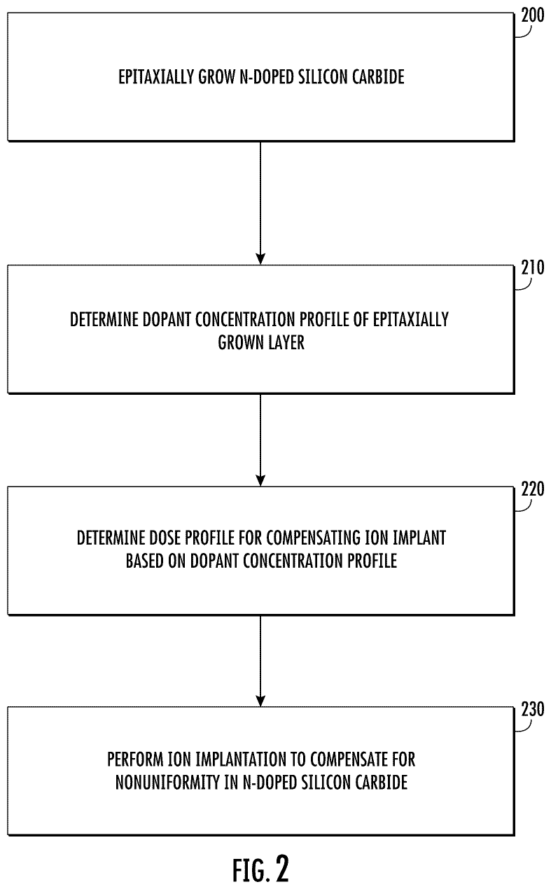

FIG. 2 shows the sequence illustrated in FIGS. 1A-1C;

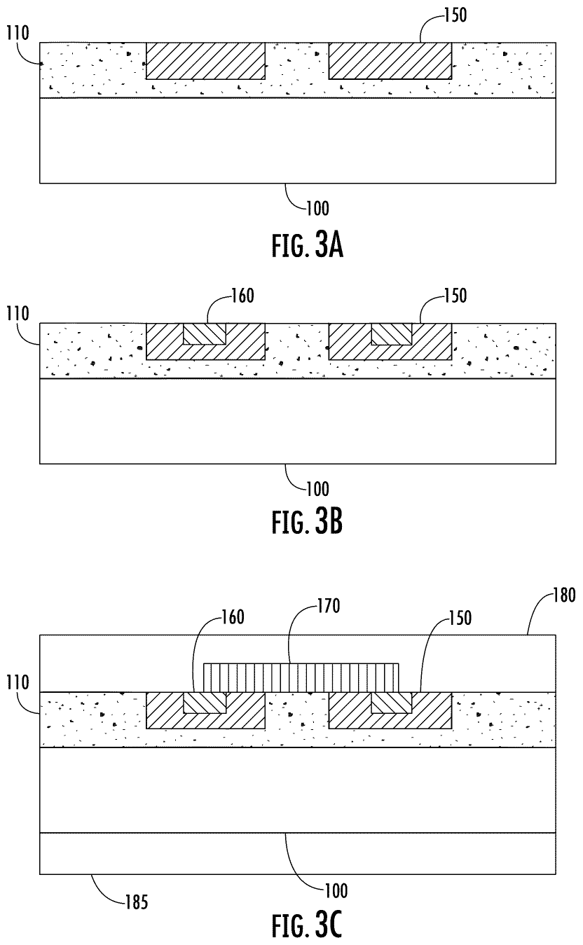

FIGS. 3A-3C show additional fabrication processes for forming a SiC planar MOSFET;

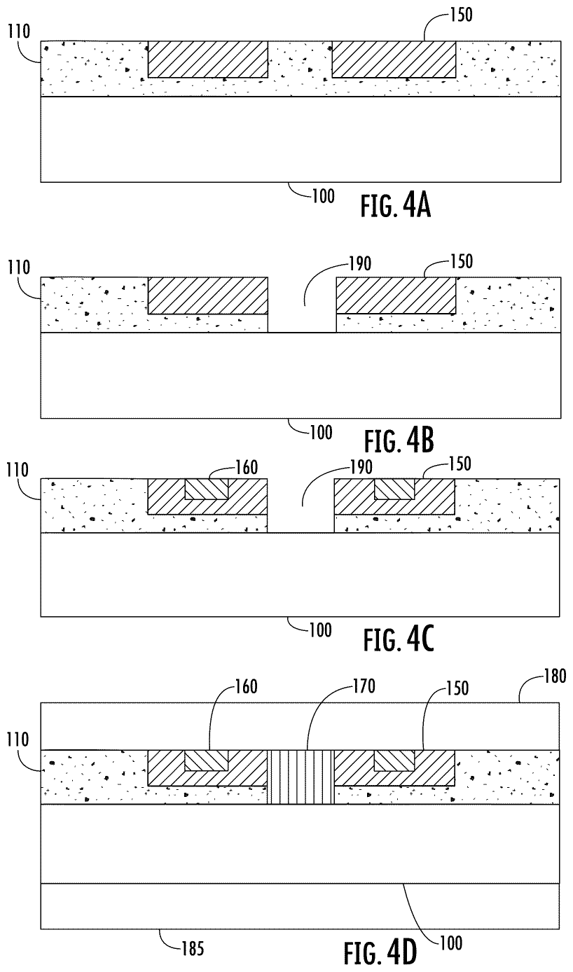

FIGS. 4A-4D show additional fabrication processes for forming a SiC trench MOSFET;

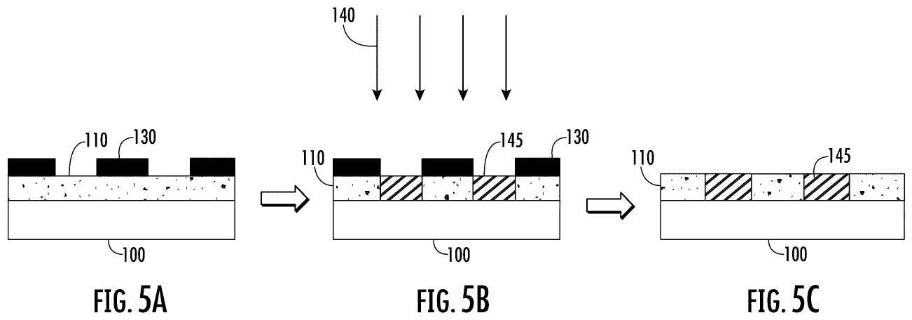

FIGS. 5A-5C show additional fabrication processes for forming the p-type columns;

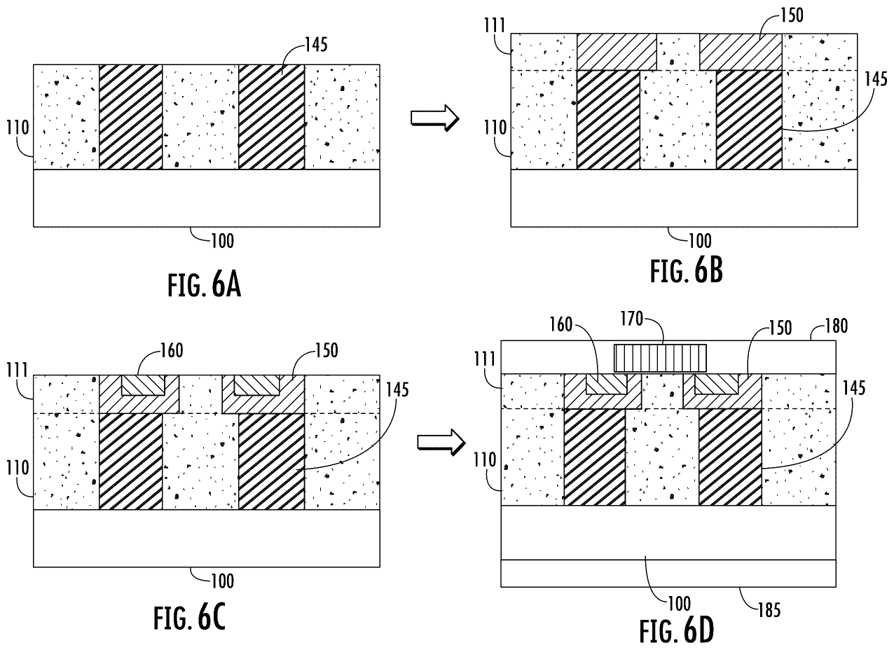

FIGS. 6A-6D show additional fabrication processes for forming a SiC super junction MOSFET;

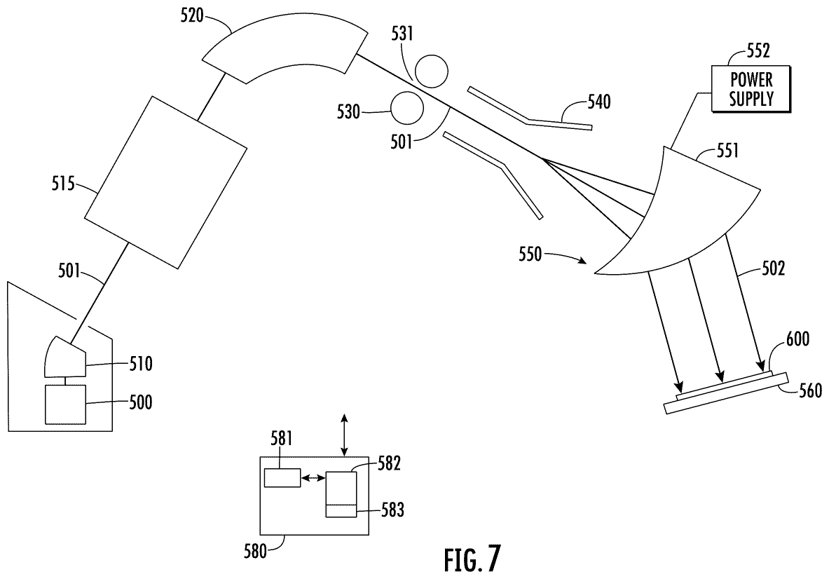

FIG. 7 shows an ion implantation system that may be used to perform the compensating implant.

### DETAILED DESCRIPTION

The present disclosure describes the use of compensating implants to enable the formation of a uniformly doped epitaxial silicon carbide layer in a silicon carbide (SiC) Metal Oxide Semiconductor Field Effect Transistor (MOSFET). This technique is applicable to various types of SiC MOSFETs, including planar, trench and super junction MOSFETs.

FIGS. 1A-1C show cross-sectional views of the workpiece as the SiC MOSFET is being fabricated. The views in FIGS. 1A-1C are common for SiC planar MOSFETs, SiC trench MOSFETs and SiC super junction MOSFETs. FIG. 2 shows the sequence of operations that correspond to FIGS. 1A-1C.

First, as shown in FIG. 1A, a substrate 100 is provided. This substrate may be an n-type substrate, such as an n-type SiC substrate. Since this substrate is used to form the drain of the MOSFET, it may have a high concentration of n-type dopant and may be referred to as an n+substrate. Much of the MOSFET device will be fabricated on top of this substrate 100. Next, as shown in Box 200 of FIG. 2 and in FIG. 1B, an n-doped silicon carbide layer is epitaxially grown on the substrate 100. This epitaxially grown layer 110 may be between about 2 microns and 10 microns thick, although other thicknesses may also be used. This layer is typically created using an epitaxy reactor. The epitaxy reactor introduces silicon, carbon, and a first n-type dopant species, such as nitrogen or phosphorus, into the reactor. In some embodiments, the silicon and carbon may be introduced using gasses that may include one or more of SiCl₄, CH₄ or C₇H₈. These species combine to create the epitaxially grown layer 110 that comprises silicon carbide in combination with n-type dopants. This is referred to as in-situ doping. Typically, the dopant concentration of the epitaxially grown layer 110 is not uniform across the entirety of the substrate 100. For example, the dopant concentration may be greater near the center and decrease toward the outer edge of the substrate 100.

Thus, as shown in Box 210, the dopant concentration of the epitaxially grown layer 110 as a function of position on the workpiece is determined. In this disclosure, the term “position” refers to the coordinates that are parallel to the surface of the workpiece. Thus, in this disclosure, the phrase “dopant concentration as a function of position” refers to the dopant concentration as measured at different positions on the workpiece. The position may be referenced using cartesian coordinates, such as x and y, or using polar coordinates, such as r and θ. In some embodiments, the dopant concentration is taken at a single depth at each position, or is an average dopant concentration at a plurality of depths. In other embodiments, the dopant concentration may also include a depth component. This depends on the measurement technique being used. In all embodiments, the result of these measurements may also be referred to as the dopant concentration profile. The result is a graph or table that associates position on the workpiece to a measured dopant concentration. Note that the term “position” refers to the two dimensional position taken along the two larger dimensions of the workpiece (length and width) and not to thickness.

In some embodiments, this dopant concentration profile may be created using a metrology tool. In some embodiments, this testing is non-destructive. In one specific example, capacitive voltage (CV) testing is used to measure dopant concentration as a function of position on the workpiece. One such example is a corona-based non-contact capacitive voltage (CnCV) testing. Other non-destructive testing techniques include mercury-probe, scanning-capacitance microscopy or micro Fourier-Transform Infrared Spectroscopy (Micro FTIR). In these embodiments, the dopant concentration of the layer grown in Box 200 and FIG. 1B may be measured directly.

Thus, in some embodiments, the dopant concentration profile may be measured for each workpiece after each epitaxially grown layer is created. However, to increase throughput, the dopant concentration profile may be measured for one workpiece and that dopant concentration profile may then be used for a plurality of subsequent workpieces. Thus, Box 210 may not be performed each time Box 200 is performed, rather Box 210 may be performed at regular intervals, such as after a predetermined number of workpieces or a predetermined duration of time.

In other embodiments, the method of determining dopant concentration as a function of position on the workpiece may be a destructive process, which destroys the workpiece being tested. These methods may include electrochemical capacitance-voltage profiling (ECV), transmission-line measurement (TLM), Hall measurement or Hall profiling. In these embodiments, rather than measuring the dopant concentration on the workpiece being fabricated in FIGS. 1A-1C, a sacrificial workpiece is used. In this sequence, the sacrificial workpiece may be a n+ substrate, similar to that used in FIG. 1A. Additionally, as shown in FIG. 1B, a sacrificial n-type layer may be epitaxially grown on this substrate using the same epitaxy reactor that is used to fabricate the production workpieces. The dopant concentration profile of this sacrificial epitaxially grown layer is then determined using any suitable method. The sacrificial workpiece may then be discarded. The dopant concentration profile as measured on this sacrificial epitaxially grown layer is then used for each production workpiece. In other words, it is assumed that the dopant concentration profile that was created in the epitaxially grown layer on the workpiece currently being fabricated is approximately the same as that measured for the sacrificial workpiece. The results from the sacrificial workpiece may then be applied to a plurality of workpieces. In some embodiments, a new sacrificial workpiece is fabricated and measured at regular intervals, such as after a predetermined number of workpieces or predetermined amount of time. In this way, the dopant concentration profile is calibrated periodically and remains accurate.

In all of these embodiments, a dopant concentration profile as a function of position associated with the epitaxy reactor is generated. This dopant concentration profile is then used to determine the parameters for a compensating ion implantation process, as shown in Box 220. Specifically, a dose profile may be generated based on this dopant concentration profile. For example, the dose profile for the compensating ion implantation process may have an inverse relationship relative to the dopant concentration profile. In other words, in positions where the dopant concentration is high, the amount of dopant added by the ion implantation process may be reduced. In contrast, in positions where the dopant concentration is low, the amount of dopant added by the ion implantation process may be increased. Thus, for each position on the workpiece, a recommended dose is determined so that the total dopant concentration in the epitaxially grown layer 110 contributed by the in-situ doping and the compensating ion implantation is roughly equal across the workpiece. In certain embodiments, the epitaxially grown layer 110 is in-situ doped such that the maximum concentration of n-type dopant is less than or equal to the desired concentration. In this way, one ion implantation of additional n-type dopant may be used to create a uniform dopant concentration profile.

Then, as shown in Box 230 and in FIG. 1C, a compensating ion implantation process is performed. The compensating ion implantation process implants a second n-type dopant species 120, such as phosphorus or nitrogen. This compensating implant may be performed using a scanning spot beam. The scanning ion beam may be manipulated such that its dwell time at each location is determined based on the dose profile, as determined earlier. An ion implanter that generates a spot beam is shown in FIG. 7 and will be described later.

After the compensating implant is completed, the uniformity of the dopant concentration in the epitaxially grown layer 110 is much improved. For example, in certain systems, the dopant concentration varies by about 3-5% across the workpiece. By using this compensating implant, that variation may be reduced by 50% or more. In some embodiments, the variation in dopant concentration across the workpiece may be reduced to 1% or less. Additionally, the compensating implant may be used to correct for other issues. For example, the compensating implant may be used if the dopant concentration of the in-situ doped epitaxially grown layer is lower than desired.

Note that this sequence may be performed in different orders. For example, Box 210 and Box 220 may be performed before Box 200, especially if a sacrificial workpiece is used. Thus, in that embodiment, the sequence may be Box 210, Box 220 and then multiple repetitions of Boxes 200 and 230.

This sequence is common for all MOSFETs. FIGS. 3A-3C show an additional sequence of operations that is performed to fabricate a planar SiC MOSFET. First, as shown in FIG. 3A, p-wells 150 are created in the epitaxially grown layer 110. This may be done by applying a mask on top of the epitaxially grown layer 110 and performing an ion implantation of a p-type dopant species, such as aluminum. This ion implantation may be performed using the same ion implanter as was used in FIG. 1C, or may be a different ion implanter. For example, an ion implanter that utilizes a ribbon ion beam may be used for the implant in FIG. 3A.

Next, as shown in FIG. 3B, source regions 160 are created. These source regions 160 are heavily n-doped regions. The source regions 160 may have a thickness of about 200 nanometers. These source regions 160 may be created by applying a second mask on top of the epitaxially grown layer 110, wherein the exposed regions correspond to portions of the p-wells 150. An ion implantation of a third n-type species, such as phosphorus or nitrogen, may be performed to create these regions. This ion implantation may be performed using the same ion implanter as was used in FIG. 3A. Note that the first n-type species, the second n-type species and the third n-type species may all be the same species or may be two or more different species.

Lastly, as shown in FIG. 3C, the gate 170 is disposed on the top surface of the epitaxially grown layer 110, and spans between the source regions 160. Next, contacts 180 to the source regions 160 and gate 170 are provided on the top of the workpiece, while contacts 185 for the drain are provided on the bottom of the workpiece.

FIGS. 4A-4D show an additional sequence of operations that is performed to fabricate a trench SiC MOSFET. First, as shown in FIG. 4A, p-wells 150 are created in the epitaxially grown layer 110. This may be done by applying a mask on top of the epitaxially grown layer 110 and performing an ion implantation of a p-type dopant species, such as aluminum. This ion implantation may be performed using the same ion implanter as was used in FIG. 1C, or may be a different ion implanter. For example, an ion implanter that utilizes a ribbon ion beam may be used for the implant in FIG. 4A. In other embodiments, a mask may not be used. For example, a blanket implant of p-type dopant species may be performed across an entirety of the workpiece. In yet another embodiment, the p-type dopant species does not form two p-wells, as was shown in FIG. 4A. Rather, one large p-well may be formed, which is subsequently divided into two p-wells by the trench.

A trench 190 is then etched into the epitaxially grown layer 110 through or between the one or more p-wells 150. This may be performed using a standard etching process, such as reactive ion etching using, for example, SF₆ and oxygen, CHF₃ and oxygen, CH₄ and oxygen or another suitable species. The depth of the trench 190 may be more than 700 nanometers. In certain embodiments, the trench 190 may have a depth that is equal to or greater than 1.5 μm. In certain embodiments, the depth of the trench 190 may be up to 2.5 μm or more. In certain embodiments, an oxide layer (not shown) may be disposed along the sidewalls of the trench 190. The oxide layer may be grown by annealing in oxygen.

Next, as shown in FIG. 4C, source regions 160 are created. These source regions 160 are heavily n-doped regions. These source regions 160 may be created by applying a second mask on top of the epitaxially grown layer 110, wherein the exposed regions correspond to portions of the one or more p-wells 150. An ion implantation of a third n-type species, such as phosphorus or nitrogen, may be performed to create these regions. This ion implantation may be performed using the same ion implanter as was used in FIG. 4A. Note that the first n-type species, the second n-type species and the third n-type species may all be the same species or may be two or more different species.

Lastly, the gate 170 is disposed in the trench 190 of the epitaxially grown layer 110. A passivation layer, such as phosphosilicate glass, is deposited around the gate 170. Next, contacts 180 to the source regions 160 and gate 170 are provided on the top of the workpiece, while contacts 185 for the drain are provided on the bottom of the workpiece.

Note that this sequence may be performed in a different order. For example, the trench 190 may be created before FIG. 4A or after FIG. 4C, if desired.

FIGS. 5A-5C and 6A-6D show an additional sequence of operations that is performed to fabricate a super junction SiC MOSFET. FIGS. 5A-5C, in conjunction with FIGS. 1A-1C, show the creation of the epitaxially grown layer 110 and the p-type columns. FIGS. 6A-6D show the operations to add the source regions, gate and contacts.

After FIG. 1C, p-type columns may be formed. First, as shown in FIG. 5A, a mask 130 is applied on portions of the epitaxially grown layer 110. The regions that are not covered by the mask 130 will form the p-type columns 145. As shown in FIG. 5B, a first p-type dopant species 140, such as aluminum, is implanted into the epitaxially grown layer 110. This implant may be performed using the same ion implanter that was used for the compensating implant, or may be a different ion implanter. The introduction of the first p-type dopant species creates p-type columns 145. In some embodiments, the energy of the ion implant is selected so that the dopant species are implanted in the entire thickness of the epitaxially grown layer 110. Thus, the thickness of this grown layer is limited by the ability to implant ions into the entire thickness. Therefore, each epitaxial growth process may be limited to roughly 1 μm.

Next, as shown in FIG. 5C, the mask 130 is removed and the workpiece is annealed to repair the damage caused by the implant process.

After this, the operations shown in FIGS. 1B-1C and 5A-5C are repeated a plurality of times to achieve the structure with a sufficiently thick epitaxially grown layer, which may be 10 μm or more, as shown in FIG. 6A. FIGS. 6B-6D show cross-sections as the fabrication of the super junction SiC MOSFET continues. First, the sequence shown in FIGS. 1B-1C may be repeated one more time to create an additional epitaxial layer 111 that will be used to form the p-wells 150. A compensating ion implantation may then be performed in the additional epitaxial layer 111. In some embodiments, the non-uniformity of this additional epitaxial layer 111 is assumed to be the same as that which was measured for the epitaxially grown layer 110. In other embodiments, the non-uniformity of this additional epitaxial layer 111 may be measured using any of the techniques described above. Then, a second mask is applied to the top surface of the additional epitaxial layer 111. The dimensions of this second mask are different from the mask 130 to allow the formation of p-wells 150 that are larger than the p-type columns 145, as shown in FIG. 6B. A second p-type species is then implanted into the additional epitaxial layer 111.

In another embodiment, the p-wells 150 are formed directly on the p-type columns 145 without the additional epitaxial layer 111. FIG. 6C shows the source regions 160 that are implanted in the p-wells 150. This may be performed by applying a third mask on top of the additional epitaxial layer 111, wherein regions of the p-wells 150 are exposed. A third n-type dopant species, such as phosphorus or nitrogen, is then implanted. This implant may be performed using the same implanter as described above. Note that the first n-type species, the second n-type species and the third n-type species may all be the same species or may be two or more different species. Additionally, the first p-type species and the second p-type species may be the same species or may be different. Finally, as shown in FIG. 6D, the gate 170 is disposed on the top surface of the epitaxially grown layer, and spans between the source regions 160. Next, contacts 180 to the source regions 160 and gate 170 are provided on the top of the workpiece, while contacts 185 for the drain are provided on the bottom of the workpiece.

FIG. 7 shows a spot beam ion implantation system that may be used for performing the compensating ion implant according to one embodiment.

The spot beam ion implantation system includes an ion source 500 comprising a plurality of chamber walls defining an ion source chamber. In certain embodiments, the ion source 500 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHz. Further, the power supplied by the RF power supply may be pulsed.

In another embodiment, a cathode is disposed within the ion source chamber. A filament is disposed behind the cathode and energized so as to emit electrons. These electrons are attracted to the cathode, which in turn emits electrons into the ion source chamber. This cathode may be referred to as an indirectly heated cathode (IHC), since the cathode is heated indirectly by the electrons emitted from the filament.

Other embodiments are also possible. For example, the plasma may be generated in a different manner, such as by a Bernas ion source, a capacitively coupled plasma (CCP) source, microwave or ECR (electron-cyclotron-resonance) ion source. The manner in which the plasma is generated is not limited by this disclosure.

One chamber wall, referred to as the extraction plate, includes an extraction aperture. The extraction aperture may be an opening through which the ions 501 generated in the ion source chamber are extracted and directed toward a workpiece 600. The extraction aperture may be any suitable shape. In certain embodiments, the extraction aperture may be oval or rectangular shaped, having one dimension, referred to as the width (x-dimension), which may be much larger than the second dimension, referred to as the height (y-dimension).

Disposed outside and proximate the extraction aperture of the ion source 500 are extraction optics 510. In certain embodiments, the extraction optics 510 comprises one or more electrodes. Each electrode may be a single electrically conductive component with an aperture disposed therein. Alternatively, each electrode may be comprised of two electrically conductive components that are spaced apart so as to create the aperture between the two components. The electrodes may be a metal, such as tungsten, molybdenum or titanium. One or more of the electrodes may be electrically connected to ground. In certain embodiments, one or more of the electrodes may be biased using an electrode power supply. The electrode power supply may be used to bias one or more of the electrodes relative to the ion source so as to attract ions through the extraction aperture. The extraction aperture and the aperture in the extraction optics are aligned such that the ions 501 pass through both apertures.

Located downstream from the extraction optics 510 is a mass analyzer 520. An acceleration/deceleration column 515 may be positioned between the extraction optics 510 and mass analyzer 520. The mass analyzer 520 uses magnetic fields to guide the path of the extracted ions 501. The magnetic fields affect the flight path of ions according to their mass and charge. A mass resolving device 530 that has a resolving aperture 531 is disposed at the output, or distal end, of the mass analyzer 520. By proper selection of the magnetic fields, only those ions 501 that have a selected mass and charge will be directed through the resolving aperture 531. Other ions will strike the mass resolving device 530 or a wall of the mass analyzer 520 and will not travel any further in the system. The ions that pass through the mass resolving device 530 may form a spot beam.

The spot beam may then enter a scanner 540 which is disposed downstream from the mass resolving device 530. The scanner 540 causes the spot beam to be fanned out into a plurality of divergent ion beamlets. In other words, the scanner 540 creates diverging ion trajectory paths. The scanner 540 may be electrostatic or magnetic. The scanner 540 may comprise spaced-apart scan plates connected to a scan generator. The scan generator applies a scan voltage waveform, such as a sawtooth waveform, for scanning the ion beam in accordance with the electric field between the scan plates. Angle corrector 550 is designed to deflect ions in the scanned ion beam to produce scanned ion beam 502 having parallel ion trajectories, thus focusing the scanned ion beam. Specifically, the angle corrector 550 is used to alter the diverging ion trajectory paths into substantially parallel paths of a scanned ion beam 502. In particular, angle corrector 550 may comprise magnetic pole pieces 551 which are spaced apart to define a gap and a magnet coil (not shown) which is coupled to a power supply 552. The scanned ion beam 502 passes through the gap between the magnetic pole pieces 551 and is deflected in accordance with the magnetic field in the gap. The magnetic field may be adjusted by varying the current through the magnet coil. Beam scanning and beam focusing are performed in a selected plane, such as a horizontal plane.

The workpiece 600 is disposed on a movable workpiece holder 560.

In certain embodiments, the forward direction of the ion beam is referred to as the Z-direction, the direction perpendicular to this direction and horizontal may be referred to as the first direction or the X-direction, while the direction perpendicular to the Z-direction and vertical may be referred to as the second direction or the Y-direction. In this example, it is assumed that the scanner 540 scans the spot beam in the first direction while the movable workpiece holder 560 is translated in the second direction. The rate at which the scanner 540 scans the spot beam in the first direction may be referred to as beam scan speed or simply scan speed.

Thus, in operation, the movable workpiece holder 560 moves in the second direction from a first position, which may be above the scanned ion beam 502 to a second position, which may be below the scanned ion beam 502. The movable workpiece holder 560 then moves from the second position back to the first position. During this time, the spot beam is being scanned in the first direction, ensuring that the entirety of the workpiece 600 is exposed to the spot beam.

A controller 580 is also used to control the system. The controller 580 has a processing unit 581 and an associated memory device 582. This memory device 582 contains the instructions 583, which, when executed by the processing unit, enable the system to perform the functions described herein. This memory device 582 may be any non-transitory storage medium, including a non-volatile memory, such as a FLASH ROM, an electrically erasable ROM or other suitable devices. In other embodiments, the memory device 582 may be a volatile memory, such as a RAM or DRAM. In certain embodiments, the controller 580 may be a general purpose computer, an embedded processor, or a specially designed microcontroller. The actual implementation of the controller 580 is not limited by this disclosure. The controller 580 may be in communication with the scanner 540, and the movable workpiece holder 560, and may be configured to modify the scan speed of scanner 540 and/or the speed of the movable workpiece holder 560 to achieve the dose profile determined in Box 220.

The methods described herein have many advantages. First, for planar and trench MOSFETs, the n-type dopant concentration helps determine the on resistance of the device. If the n-type dopant concentration falls below a certain value, the on resistance of the device may be unacceptably high. For example, assume that there is typically a linear relationship between dopant concentration and distance from the center of the workpiece. If the n-type concentration is 10% less at the edge of the workpiece, the yield of the entire workpiece may drop below 70%. By performing a compensating ion implant, this decrease in concentration may be reduced, improving yields considerably. Further, as noted above, the compensating implants may be used to increase the dopant concentration of the entire epitaxially grown layer if the in-situ doping is less than desired.

Super junction MOSFETs rely on charge balance between the p-type columns and the rest of the epitaxially grown layer (which is n-doped). Charge imbalance may significantly affect performance, including parameters such as breakdown voltage and on resistance. For example, a charge imbalance of 10% may result in a decrease in breakdown voltage of up to 50%. By performing a compensating ion implant, this variation in charge imbalance may be reduced, improving yields considerably.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of fabricating a planar silicon carbide MOSFET, comprising:
growing an epitaxial layer on a substrate using an epitaxy reactor, wherein the epitaxial layer is in-situ doped using a first n-type species;
determining a dose profile to compensate for non-uniformity of a dopant concentration of the epitaxial layer;
performing a compensating ion implantation using a second n-type species into the epitaxial layer based on the dose profile;
implanting a p-type species into portions of the epitaxial layer to form p-wells;
implanting a third n-type species into the p-wells to form source regions;
forming a gate on a top surface of the epitaxial layer between the p-wells; and
adding contacts for the source regions, the gate and a drain region.

2. The method of claim 1, further comprising:
measuring the dopant concentration of the epitaxial layer as a function of position after the growing, wherein the dopant concentration as a function of position defines the non-uniformity of the dopant concentration.

3. The method of claim 2, wherein the measuring is performed non-destructively.

4. The method of claim 1, wherein the non-uniformity of the dopant concentration is determined using a different substrate.

5. The method of claim 4, further comprising:
growing a sacrificial epitaxial layer on a sacrificial substrate using the epitaxy reactor, wherein the sacrificial epitaxial layer is in-situ doped using the first n-type species; and
measuring the dopant concentration of the sacrificial epitaxial layer as a function of position, wherein the dopant concentration as a function of position is used as the non-uniformity of the dopant concentration of the epitaxial layer.

6. The method of claim 5, wherein the measuring is performed destructively.

7. A method of fabricating a silicon carbide super junction MOSFET, comprising:
growing an epitaxial layer on a substrate using an epitaxy reactor, wherein the epitaxial layer is in-situ doped using a first n-type species;
determining a dose profile to compensate for non-uniformity of a dopant concentration of the epitaxial layer;
performing a compensating ion implantation using a second n-type species into the epitaxial layer based on the dose profile;
implanting a first p-type species into portions of the epitaxial layer to form p-doped columns;
repeating the growing, performing and implanting a plurality of times to achieve a desired height of the p-doped columns; and
after the desired height has been achieved:
implanting a second p-type species into portions of the epitaxial layer to form p-wells;
implanting a third n-type species into the p-wells to form source regions;
forming a gate on a top surface of the additional epitaxial layer between the p-wells; and
adding contacts for the source regions, the gate and a drain region.

8. The method of claim 7, further comprising:
measuring the dopant concentration of the epitaxial layer as a function of position after the growing, wherein the dopant concentration as a function of position defines the non-uniformity of the dopant concentration.

9. The method of claim 8, wherein the measuring is performed non-destructively.

10. The method of claim 8, wherein the non-uniformity of the dopant concentration is determined using a different substrate.

11. The method of claim 10, further comprising:
growing a sacrificial epitaxial layer on a sacrificial substrate using the epitaxy reactor, wherein the sacrificial epitaxial layer is in-situ doped using the first n-type species; and
measuring the dopant concentration of the sacrificial epitaxial layer as a function of position, wherein the dopant concentration as a function of position is used as the non-uniformity of the dopant concentration of the epitaxial layer.

12. The method of claim 11, wherein the measuring is performed destructively.

13. The method of claim 8, further comprising growing an additional epitaxial layer after the desired height is achieved, and forming the p-wells in the additional epitaxial layer.

14. The method of claim 13, wherein the non-uniformity of the dopant concentration of the additional epitaxial layer is assumed to be the same as the epitaxial layer.

15. A method of fabricating a silicon carbide trench MOSFET, comprising:
growing an epitaxial layer on a substrate using an epitaxy reactor, wherein the epitaxial layer is in-situ doped using a first n-type species;
determining a dose profile to compensate for non-uniformity of a dopant concentration of the epitaxial layer;
performing a compensating ion implantation using a second n-type species into the epitaxial layer based on the dose profile;
implanting a p-type species into portions of the epitaxial layer to create a p-type region;
etching a trench into the p-type region to form p-wells;
implanting a third n-type species into the p-wells to form source regions;
forming a gate in the trench; and
adding contacts for the source regions, the gate and a drain region.

16. The method of claim 15, further comprising:
measuring the dopant concentration of the epitaxial layer as a function of position after the growing, wherein the dopant concentration as a function of position defines the non-uniformity of the dopant concentration.

17. The method of claim 16, wherein the measuring is performed non-destructively.

18. The method of claim 15, wherein the non-uniformity of the dopant concentration is determined using a different substrate.

19. The method of claim 18, further comprising:
growing a sacrificial epitaxial layer on a sacrificial substrate using the epitaxy reactor, wherein the sacrificial epitaxial layer is in-situ doped using the first n-type species; and
measuring the dopant concentration of the sacrificial epitaxial layer as a function of position, wherein the dopant concentration as a function of position is used as the non-uniformity of the dopant concentration of the epitaxial layer.

20. The method of claim 19, wherein the measuring is performed destructively.
